(19) United States
(12) Patent Application Publication
(10) Pub. No.: US 2026/0282203 A1
(43) Pub. Date: Sep. 17, 2026

(54) RF COIL RESONATOR SYSTEMS AND METHODS

(71) Applicant: Standard BioTools Canada Inc., Markham (CA)

(72) Inventors: Alexander Loboda, Thornhill (CA); Emil Stratulativ, Toronto (CA); Maxim Voronov, Markham (CA)

(73) Assignee: Standard BioTools Canada Inc., Markham, ON (CA)

(21) Appl. No.: 18/873,908

(22) PCT Filed: Jun. 15, 2023
(86) PCT No.: PCT/US2023/025373

§ 371 Date: Dec. 11, 2024

Related U.S. Application Data
(60) Provisional application No. 63/353,177, filed on Jun. 17, 2022.

(51) Int. Cl. H05H 1/46; H05H 1/30

(52) U.S. Cl. CPC H05H 1/4652; H05H 1/30

(57) ABSTRACT

Embodiments described include subsystems to supply RF power to an inductively coupled plasma (ICP) torch. The disclosure addresses some technical aspects of RF power converter as well as design of the load coil and resonating RF tank circuit for ICP. Systems and methods described herein cancel RF on the axis due to the symmetry of applied voltages and the symmetry of the load coil. Thus, RF balancing is accomplished by design without the need for finding and tuning the optimal RF voltage ratio. Embodiments also allow for high RF currents and low RF voltages, reducing the risk of RF breakdown outside the torch. Transistors may be used to deliver RF power. As a result, a more compact ICP assembly can be used.

### CROSS-REFERENCES TO RELATED APPLICATIONS

This application claims the benefit of priority to U.S. Provisional Application No. 63/353,177, filed Jun. 17, 2022, the entire contents of all of which are incorporated herein by reference for all purposes.

### BACKGROUND

Inductively coupled plasmas (ICPs) find numerous applications ranging from semiconductor processing to garbage incineration, material treatment, and powder processing setups, to analytical instrumentation such as ICP-MS (ICP mass spectrometry), ICP OES (ICP optical emission spectroscopy), to mass cytometry.

Mass cytometry is becoming a popular tool for flow cytometry analysis of biological samples as well as for biological imaging of tissue samples. Mass cytometry principle is based on revealing the concentrations of antigens in individual biological cells using affinity probes with elemental tags attached to them. Once the cells are tagged, the readout constitutes sending these cells into an inductively coupled plasma ion source where the elemental tags on each cell are atomized and ionized. Ionized cloud from each cell containing elemental tags is sampled into a mass spectrometer and the sequence of the clouds for the entire sample is recorded there. A benefit of mass cytometry approach is the large number of probes that can be applied and recorded simultaneously in one experiment. Over 40 probes recorded in one experiment has been demonstrated with this technology. Recently, the application of mass cytometry has been extended to the field of immunohistochemistry-based imaging of biological tissues. This technique is called Imaging Mass Cytometry™ (IMC™). In any of these methods an ICP torch plays a role in converting biological material into transient signals of ions from elemental tags.

ICPs typically run at frequencies from 1 MHz to 100 MHz and at power levels of 10 s of Watts at low pressure to Megawatts at atmospheric pressure. Kilowatt level ICPs operating at atmospheric pressure are employed in analytical instrumentation. The power converter for ICP takes AC/DC power from a power source and converts it into RF power. This converter is often a big, bulky, and a relatively expensive unit. Its power conversion efficiency could also be low resulting in a significant production of waste heat. Deficiencies also include reliability and reproducibility of analytical results.

These and other deficiencies have been identified when technologies such as mass cytometry find their applications among biologists. These and other needs are addressed.

### BRIEF SUMMARY

Embodiments described herein include subsystems to supply RF power to an inductively coupled plasma (ICP) torch. The disclosure addresses some technical aspects of RF power converter as well as design of the load coil and resonating RF tank circuit for ICP. Systems and methods described herein cancel RF on the axis due to the symmetry of applied voltages and the symmetry of the load coil. Thus, RF balancing is accomplished by design without the need for finding and tuning the optimal RF voltage ratio. Embodiments also allow for high RF currents and low RF voltages, reducing the risk of RF breakdown outside the torch. Transistors may be used to deliver RF power. Embodiments may result in a compact ICP assembly.

In embodiments, an RF coil resonator may include a plurality of loops. Each loop of the plurality of loops may be connected to the other loops of the plurality of loops to be electrically parallel when a voltage is applied to the plurality of loops. The RF coil resonator may in addition include a power supply in electrical communication with the plurality of loops. The power supply may be in a circuit configured to deliver a first phase of RF power to a first terminal of the plurality of loops and a second phase of RF power to a second terminal of the plurality of loops.

In embodiments, an RF power module may include a DC power supply. The RF power module may in addition include a plurality of transistors in electrical communication with the DC power supply. The RF power module may also include a plurality of gate drivers. Each gate driver of the plurality of gate drivers may be connected to a separate transistor of the plurality of transistors. The RF power module may further include a processor. The processor may be configured to control the plurality of gate drivers to open and close the plurality of transistors in order to convert DC current from the DC power supply into RF current.

Embodiments may include a method of analysis using a plasma. The method may include applying an RF voltage to a plurality of loops around a tube. The plurality of loops may be electrically parallel. A first phase of the RF voltage may be applied to a first terminal of the plurality of loops. A second phase of the RF voltage may be applied to a second terminal of the plurality of loops. The first phase may be opposite the second phase. The method may in addition include igniting the plasma in the tube.

A better understanding of the nature and advantages of embodiments of the present invention may be gained with reference to the following detailed description and the accompanying drawings.

### BRIEF DESCRIPTION OF THE DRAWINGS

FIG. 1 shows an example of a load coil configuration according to embodiments of the present invention.

FIG. 2 shows an example of a load coil configuration according to embodiments of the present invention.

FIG. 3 shows an example of a load coil configuration with half-turn coils according to embodiments of the present invention.

FIG. 4 shows a system including a full bridge driving the resonant circuit of a load coil and capacitor modules according to embodiments of the present invention.

FIG. 5 shows the layout of a load coil, resonating capacitors, inductors, and an RF driving circuit according to embodiments of the present invention.

FIG. 6 shows an integrated plasma torch module with a compact solid state RF generator according to embodiments of the present invention.

FIG. 7A shows a load coil around a tube according to embodiments of the present invention.

FIG. 7B shows operation of an ICP torch according to embodiments of the present invention.

FIGS. 8A and 8B show results of simulations of distribution of the current density inside turns of the load coil according to embodiments of the present invention.

FIG. 9 is a flowchart of a process associated with a method of analysis using a plasma according to embodiments of the present invention.

### DETAILED DESCRIPTION

While inductively coupled plasmas (ICPs) are used in many applications, the power delivery system has several disadvantages, including the cost of the RF generator and the amount of power needed to operate an analytical torch (on a scale of 1 to 2 kW). Relatively low efficiency of RF generator and power delivery circuits can lead to even higher electrical power consumption. ICP power delivery circuits may have efficiency on the scale of 60%. This means that at 1.5 kW RF power going into the ICP load coil, the circuits would consume an additional 1 kW of electrical power, which is converted into heat that needs to be removed from the electronic components. A circuit with about 90% efficiency of RF power delivery would be beneficial to the users and to the instrument designers. The circuit may simplify heat management for instrument designers and decrease costs of electricity and air conditioning to the end users. Another disadvantage is the RF coupling of driving voltage to the plasma that can cause a secondary discharge between the plasma and another electrode such as a sampler electrode, as described in U.S. Pat. No. 4,501,965. Careful balancing of RF coil voltage is often required. ICP systems and methods are also described in US Patent Publication No. 2021/0404968. Another disadvantage is a high voltage (up to several kV) that is applied to the usual helical load coil with a serial connection of its turns. In this construction, an electrical breakdown between the coil turns can occur. The coil may be additionally insulated to avoid the breakdown, which may cause additional expense and complexity.

Another disadvantage of existing ICP setups is aging of RF load coils and periodic replacement of the coils. A load coil encounters a significant amount of heat flux. This heat can raise the temperature of the load coil to 300° C. in the air. At this temperature, the outer layer of copper can blacken, and the load coil eventually degrades, requiring periodic replacement. Liquid cooling of the load coil can be used to overcome this problem but adds complexity to RF circuits. Considerations for compatibility with high RF voltage on the load coil often restrict the range of cooling solutions that can be employed.

The typical load coils are usually manufactured by curving copper or silver tubes. Curving tubes results in some distortion of the coil geometrical parameters and is less accurate and precise than if the coil could be machined from a larger piece. Together with the mentioned coil periodic replacement, the imprecision of the coil geometric parameters limits reproducibility of the analytical results.

Another disadvantage of present ICP setups is axial RF currents on the axis of the plasma. Axial RF currents in the plasma can permeate into the vacuum interface of the mass spectrometer and affect ion signals. U.S. Pat. No. 4,501,965 offers one way of solving this problem by using an electrical scheme that generates RF_A and RF_B voltages in such a proportion that their net effect cancels out at one location on the axis, just in front of the sampler orifice. However, finding the proper ratio involves experimentation, and the ratio depends on the position and the shape of the plasma in the torch and its relation to the sampler position.

Some ICP setups have a problem of RF MOSFET transistors requiring a relatively high power to drive their gates. This complicates the driving circuit and adds to power losses of the overall system. Additionally, another problem is that existing vacuum tube triode based RF generators for ICP require a high voltage DC source for the triode. The high voltage DC source is a custom power supply and is relatively big and expensive in comparison to lower voltage off-the-shelf power supplies of similar power handling capacity.

Embodiments of ICP configurations and methods described herein simplify the RF generator, make RF circuits of ICP more power efficient, suppress the degradation of the load coil and make it mechanically more reproducible, reduce or remove the need for RF balancing, and reduce or eliminate axial RF currents.

### I. RF Coil Resonator

Embodiments described herein power the load coil of ICP MS using high RF currents and low RF voltages by having turns of load coils electrically parallel rather than electrically serial. The low RF voltage may allow for direct heat sinking of individual turns of the RF load coil to its base and therefore increased longevity of the load coil. Low RF voltage reduces the risk of RF breakdown on the outside of the torch and eliminates a possibility of the breakdown between the turns. This allows for reduced clearance between mechanical parts and more compact assemblies. An overvoltage condition can be created by the circuit to ignite the plasma without the risk of an electrical breakdown. Self-ignition of the plasma can simplify the ICP subsystem and make the subsystem more compact. Solid state circuits may be used for power delivery and to power the resonant tank circuits. Compactness of the ICP torch and electronics facilitates its integration with a laser ablation module for ultrafast transients. The throughput of the laser ablation-based imager is defined by the width of the transients. Thus, more compact ICP assemblies among other things facilitate progress in imaging mass spectrometry and Imaging Mass Cytometry™.

Embodiments include several main interconnected components: the load coil, the resonant RF tank circuit connected to the load coil, and the RF power delivery circuit feeding the resonant tank circuit, and the torch itself.

### A. Load Coil and RF Tank Circuit

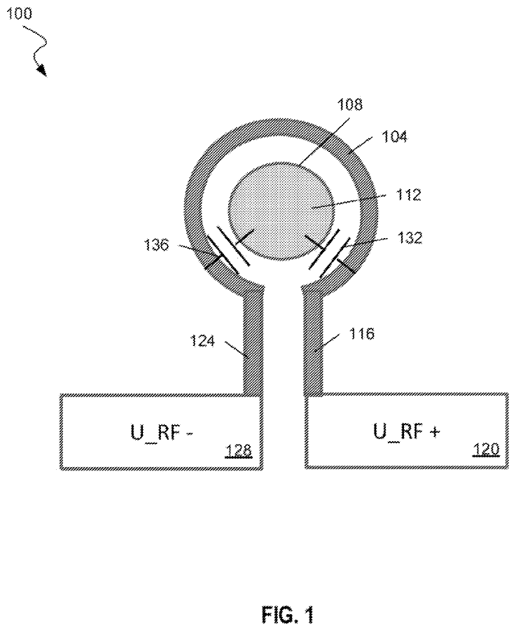

FIG. 1 shows an example of a load coil configuration 100 that leads to self-balancing of the on-axis RF potential in the plasma. A load coil 104 is around a virtual tube 108 with plasma 112. For simplicity, only one turn of load coil 104 is shown. Multiple turns of load coil 104 are possible, with each turn being a flat circular or almost circular, similar to the figure. A first terminal 116 may connect load coil 104 to the A phase 120 of an RF power supply. A second terminal 124 may connect load coil 104 to the B phase 128 of an RF power supply. Capacitor 132 illustrates capacitive coupling of phase A between load coil 104 and plasma 112. Capacitor 136 illustrates capacitive coupling of phase B between load coil 104 and plasma 112. Neither capacitor 132 nor capacitor 136 are physical capacitors.

As a result of symmetry, when the RF+A phase and the RF−B phase voltages have the same amplitudes, the RF effects cancel out and the on-axis (e.g., the longitudinal axis through the center of tube 108) potential of the plasma is zero. More details about the reasons for balancing RF in H. Niu, Fundamental studies of the plasma extraction and ion beam formation processes in inductively coupled plasma mass spectrometry, Dissertation, 1994, pp. 38-40, available at doi.org/10.31274/rtd-180813-11783. In typical analytical ICP MS instruments, the load coil has three or four turns arranged as a spiral or helix. These turns as a set of individual turns can be viewed as being connected in series. With a spiral arrangement of turns, only the turn in the middle will have the proper balancing. The outside turns will have RF voltages that are not matching each other and not canceling out. Thus, the net balancing can only be achieved in one location along the axis which is commonly setup in the area right in front of the sampler. Balancing might be achieved for a particular state of plasma (e.g., plasma power and its distance from the sampler). However, good balancing over the whole range of operating conditions can become difficult.

Embodiments may include driving the ICP with several turns connected in parallel to the same RF source. In such configurations every turn of the load coil produces RF balanced plasma (on axis) regardless of the plasma conditions and elongation. Another benefit of driving several turns in parallel is that the RF voltage needed to drive such a system at a given plasma power is lowered. Reduced voltage requirement on the load coil makes it easier to couple low-medium voltage power transistors to the load. Once the turns are connected in parallel the RF voltage is reduced but the RF current is proportionally increased in order to maintain the same RF power. This results in a fairly low inductance of the load coil and in high currents needed to maintain RF voltage across it. To minimize the impedance lowering effect of the load coil, a capacitor can be placed across the load coil of the present invention. Not all the current delivered to the plasma will be transferred to the plasma. A capacitor can help store some of this excess current thus forming a portion of the resonant tank circuit.

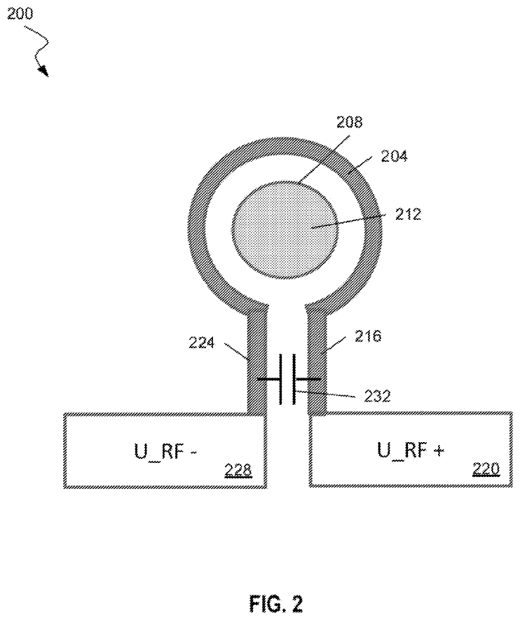

FIG. 2 shows an example of a load coil configuration 200 with a physical capacitor. A load coil 204 is around a tube 208 with plasma 212. For simplicity, only one turn of load coil 204 is shown. Multiple turns of load coil 204 are possible. A first terminal 216 may connect load coil 204 to the A phase 220 of an RF power supply. A second terminal 224 may connect load coil 204 to the B phase 228 of an RF power supply. A capacitor 232 connects to both first terminal 216 and second terminal 224.

Load coil 204 may act as an inductor, or an inductor (not shown) may also be added in series with load coil 204. The value of capacitor 232 can be chosen to mostly cancel the impedance of the inductor at the preferred operating frequency. Thus, the electrical properties of the circuit may become dominated by resistive losses of RF energy in the plasma. This arrangement is beneficial because without the resonant capacitor, parasitic inductance of connecting wires will limit the ability of the circuit to circulate high currents in the load coil while applying low voltages. The capacitor allows one to cancel out a large portion of inductive impedance of the setup. The remaining impedance is largely resistive but a portion of inductive or capacitive impedance can be created by shifting the RF frequency of the signal to above or below the resonating frequency of the setup. The load coil together with the inductors and capacitors are considered to form a resonant RF tank circuit or a portion of the resonant tank circuit. The resonant RF tank circuit may serve to balance impedance related to the resonance of the current through the load coil.

FIGS. 1 and 2 show only one turn in the load coil, but similar circuits can operate with the load coil with multiple turns connected in parallel. One can stack the turns such that each turn is connected to its dedicated driver and run the drivers in RF synchronization. An RF model showed that when the load coil contains three turns connected in parallel, the turn in the middle is screened by the outer turns and the current in the middle turn is lower than the current in the outer turns for the same voltage applied to all turns. As a result of this observation, one may conclude that the middle turn is not working as hard as the outer turns. The number of turns in the load coil might be reduced to two, which may allow for more compact load coils and torches. Another option may be to create the outer turns with higher inductance than the middle turn(s). This can be accomplished by making the outer turns with bigger diameters than the middle turn(s) or by adding parasitic inductance in the feeding legs (i.e., terminals) of the outer turns.

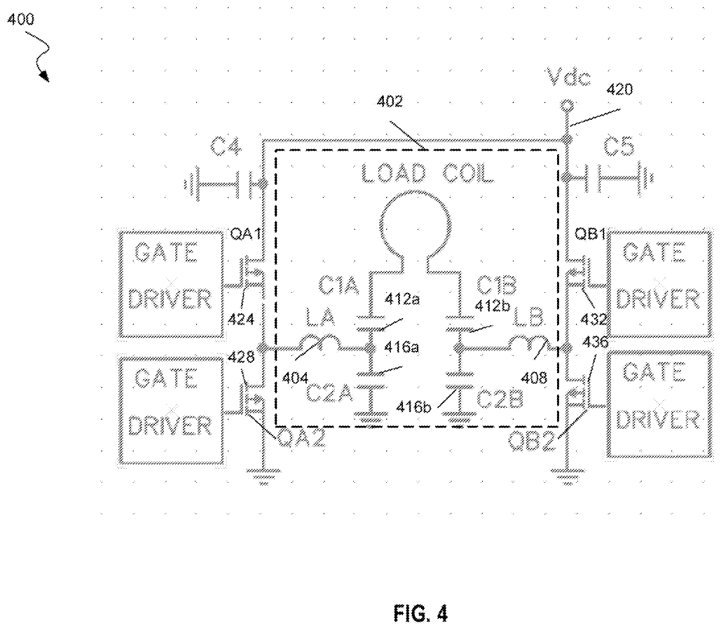

Additional design variations are available for the resonant circuit. Capacitor 232 can be replaced by two independent capacitors with each independent capacitor connecting its side of the load coil to ground. This capacitor arrangement reduces the voltage rating required for the capacitor by two times. DC blocking capacitors can be installed in series with the load coil to block DC voltages that can originate from RF drivers. Capacitive dividers can be connected to each side of the load coil. The overall capacitance of the divider can be chosen to negate most of the inductive impedance of the load coil. Having a capacitive divider allows one to inject RF at a lower amplitude into the divider and let the resonant processes increase the amplitude on the second capacitor connected directly to the load coil. Various resonant schemes for impedance transformation can be utilized to change the impedance of the load coil (with power dissipation from plasma present) and are described herein (e.g., FIG. 4).

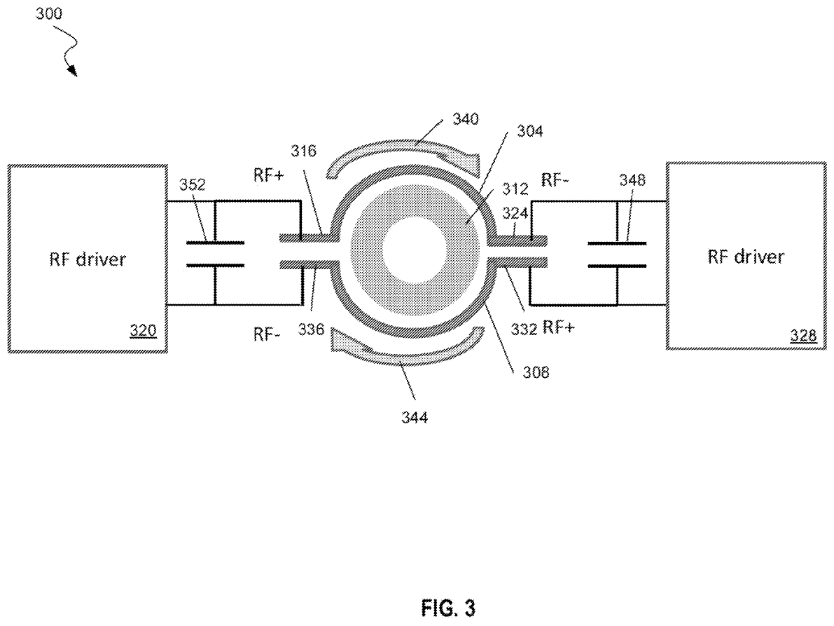

FIG. 3 shows another example of a load coil configuration 300. The single loop of a load coil in FIGS. 1 and 2 may be split into a first half-turn coil 304 and a second half-turn coil 308. First half-turn coil 304 and second half-turn coil 308 are around a plasma 312. A first terminal 316 of first half-turn coil 304 is connected to the A phase of an RF driver 320. A second terminal 324 of first half-turn coil 304 is connected to the B phase of an RF driver 328. A first terminal 332 of second half-turn coil 308 is connected to the A phase of RF driver 328. A second terminal 336 is connected to the B phase of RF driver 320. RF current flows in a clockwise direction as indicated by arrows 340 and 344. RF driver 320 and RF driver 328 may be operated in RF synchronization with each other. Resonant capacitors 348 and 352 offset the effect of low coil inductance, similar to capacitor 232 in FIG. 2.

In FIG. 3, the half-turn coils require even less RF voltage and may improve balancing further. The RF power requirements of each individual RF driver are reduced by half. While the half-turn arrangement is shown here, a one-third turn, one-quarter turn, or other fractional turn arrangements are also possible. More than one disc of half turns can be positioned along the length of the torch thus creating a setup similar to a three-turn load coil described with FIG. 1.

The half-turn or fractional turn arrangement has advantages for RF balancing. The system may have a better symmetry of RF currents in the plasma. The amplitude of RF voltage on the half-turns is reduced by 2×. Thus, an imperfection in balancing due to an asymmetry of the actual setup will be further attenuated by the reduced RF voltage applied.

### B. RF Power Delivery

Embodiments include delivering the phases of RF power to the load coil through the resonant RF tank circuit. An RF triode tube can be used to generate and deliver RF power, but such power sources are large and expensive. Additionally, RF triode tubes may only be 60-70% efficient. To address the problem of the size and cost of the RF power delivery module to the ICP MS, embodiments use high frequency power transistors instead of an RF triode tube. Because RF transistors operate at low DC voltages, the power supply for such transistors can be generic rather than custom, which often means cheaper, more compact and more efficient for the same power handling level.

Embodiments include using a switch-mode power supply (SMPS) principle at these relatively high frequencies (around 40 MHz), instead of a linear amplifier for RF power. The SMPS is made with transistors. The SMPS with transistors as drivers can be configured to operate efficiently with the inductively coupled plasma load. There are many possible configurations for that which have parallels to resonant SMPS topologies. The operation of a resonant RF power converter at 40 MHz may be facilitated by high-performance transistors, such as those based on gallium nitride (GaN). These transistors require relatively low amounts of energy at the input to switch states (Open/Close). Thus, the drivers for these transistors can be in the form of more commercially available MOSFET drivers and can be directly controlled by digital signals. This simplifies the design of control circuits and the number of stages and components needed for the RF power converter. The SMPS also provides more flexibility in the timing and shape of control signals used in the resonant converters. More will be discussed in the resonance conversion section.

An embodiment of the RF driver is a resonant converter style driver with soft switching of transistors. RF driver configurations in the field of resonant converter SMPS include (but are not limited to) the basic LLC and LCC configurations, as well as more complex configurations (e.g., LCLC). Similarly, in the field of resonant SMPS, the RF driver can be configured in many topologies (e.g., different arrangements of transistors, capacitors, and inductors). The choice can be made to fit a particular technology of RF capacitors or to minimize or reduce the effects of stray inductance or to reduce power losses in transistors and other components.

High-performance switching transistors, including GaN transistors, may be integrated into the RF driver. The RF driver can be configured as a full-bridge resonant driver (e.g., with four transistors), as a half-bridge resonant driver (e.g., one side grounded with two transistors), or as a flyback resonant driver (e.g., with one switching transistor). Multiple transistors can be used in parallel in one switch to increase power handling range.

FIG. 4 shows a system 400 including a full bridge driving the RF tank circuit 402 of a load coil and capacitor modules. RF tank circuit 402 includes impedance matching inductors LA 404 and LB 408 and capacitors C1A 412a, C1B 412b, C2A 416a, and C2B 416b. The RF power is transferred from the outputs of the bridge driver to the resonant load coil circuit by means of inductors LA 404 and LB 408.

DC power supply 420 delivers DC power to transistors driving RF tank circuit 402. RF power is delivered using transistors QA1 424, QA2 428, QB1 432, and QB2 436. Each transistor may have an associated gate driver to turn on and off the transistor. Turning on and off a transistor may allow a square wave to pass through from the driver to the output of the transistor. A square wave is described here as a simplification for illustrative purposes. In actual implementation the rise and fall times of transitions between On and Off states of transistors need to be accounted for. These transitions can be made more power efficient with the help of resonant effects in the tank circuit. The timing of opening and closing of the transistors can allow for an RF current to be delivered to RF tank circuit 402. The transistors may be GaN MOSFETs. A controller may send digital pulses to the gate drivers. The digital pulses may have parameters such as duration, frequency, and time delay. Controller can also adjust these parameters on-the-fly to optimize efficiency or to increase RF voltage or to adapt to a change in plasma conditions.

Impedance matching inductors LA 404 and LB 408 assist in the zero-volt switching operation of the GaN MOSFETs. Zero-volt switching is a technique that turns on a power transistor at the moment when the voltage across the transistor is low (near zero). To further facilitate zero-volt switching in all loading conditions, the switching frequency may be modulated such as to maintain certain phase relationship between the voltage at the output of the bridge and the voltage between the load coil terminals.

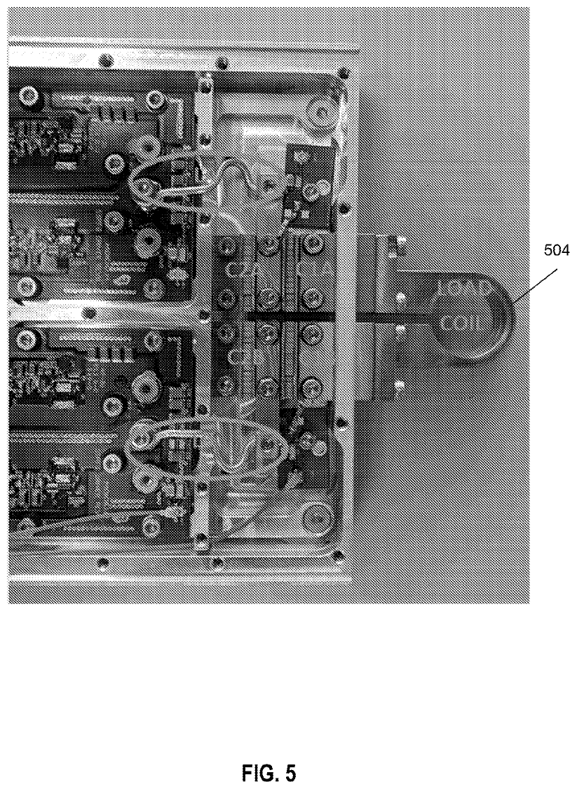

FIG. 5 shows the layout of a load coil 504, resonating capacitors, and MOSFET bridge connection by means of inductors LA and LB implemented as silver-plated copper bars connecting the bridge terminals to the resonating capacitors C1A, C1B, C2A, and C2B. FIG. 5 shows an example of system 400 from FIG. 4. FIG. 5 shows how the RF driving circuit and the load coil can be miniaturized into one package (module). The inner diameter of the load coil is 22 mm. The length of the load coil is about 2 cm.

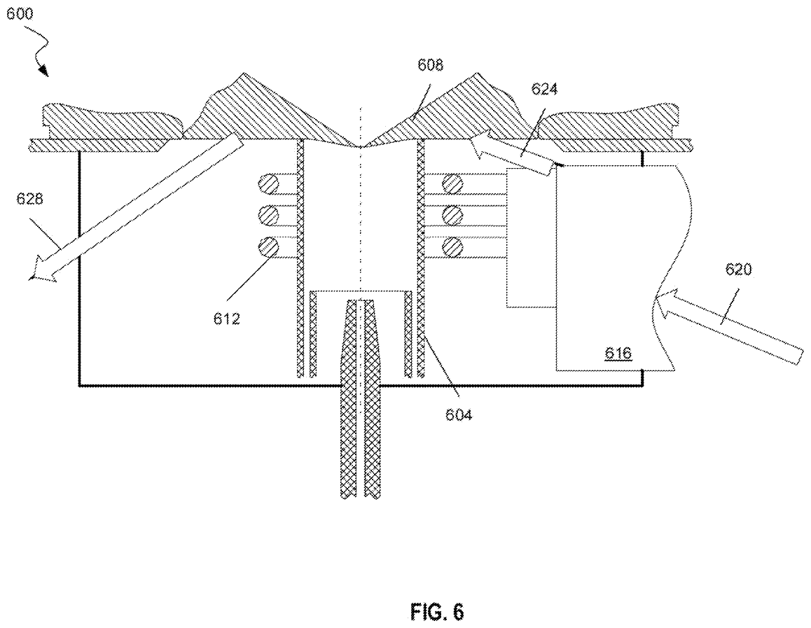

FIG. 6 shows an integrated plasma torch module 600 with a compact solid state RF generator. An ICP tube 604 for a plasma torch is sealed against a sampler 608. ICP tube 604 is surrounded by a load coil 612. Load coil 612 may be load coil 104 of FIG. 1 or load coil 204 of FIG. 2. Load coil 612 may be powered by RF generator 616, which may include the full bridge in FIG. 4. Cooling liquid flow is illustrated by arrows 620, 624, and 628. Plasma torch module 600 can share the liquid cooling for the electronics with the liquid cooling for ICP tube 604 and sampler 608, allowing for a compact cooling system.

In the sealed torch setups the pressure in the torch may be lowered below atmospheric pressure to ignite an RF discharge with relatively low RF voltage. This RF discharge can then morph into a high pressure ICP plasma by gradually increasing the pressure and the plasma power supplied to the torch. This allows one to self-ignite plasma in the torch without requiring an additional ignitor assembly or a large overvoltage of RF needed for ignition at atmospheric pressure.

The self-ignition concept is experimentally and theoretically demonstrated. The theoretical estimation of the ignition voltage is based, in our conditions, on the balance of energy of electrons received from the electrical field and loses in collisions. This results in the following approximate formula:

$$E \approx \frac{{E}_{i o n}}{e λ} \sqrt{\frac{16}{3 π} δ}$$

where E is the threshold electrical field of ignition, Eᵢₒₙ is ionization energy of Ar atom, e is absolute value of electron charge, λ is mean free path of electrons, δ is a fraction of energy transferred from an electron to an Ar atom in one collision, δ≈2.7·10⁻⁵. Because λ is inversely proportional to pressure, decreasing the Ar pressure well below the atmospheric pressure can enable self-ignition with a low voltage RF generator. Experimentally, the self-ignition may take place at pressures below about 3 Torr, which are achievable in the sealed torch by evacuation through the sampler orifice.

Moreover, the pressure in the torch can be easily brought to several atmospheres just by controlling the flow of plasma gas entering and leaving the torch. One can use smaller scale torches when operating at pressures above 1 atm. Smaller scale torches can consume less RF power to sustain plasma and due to the compactness of the plasma the smaller scale torches can facilitate faster transients for transient events such as ablation plume recording or single particle detection in plasma.

In embodiments, the sealed torch may be made in ceramic via 3D printing. Other suitable torch materials such as fused silica may be used as well. The sealed torch may be the manifold that contains the plasma. The 3D printed ceramic may allow cooling channels in the ceramic body as well as plasma gas supply channel and plasma gas removal channel. The 3D printed ceramic can be selectively metallized (with a mask) to create the turns of the load coil and soldering pads for additional RF components such as capacitors and inductors. Thus, ceramic 3D printing technology can further facilitate integration of the torch and RF electronics into a single plasma module. Such integration can include the sampler on the output of the torch and the injector plate on the input of the torch. The integrated system can allow one to operate with a short injector of only a few centimeters. A short injector may be advantageous for fast transients of ablation plumes used in Imaging Mass Cytometry™ and imaging mass spectrometry. By comparison, in some commercial systems the distance, between the ablation region and the tip of injector into the plasma is roughly 40 cm. The delay for a transient arrival and the broadening of the transient typically scales nearly proportionally to the length of the injector.

### C. Operation

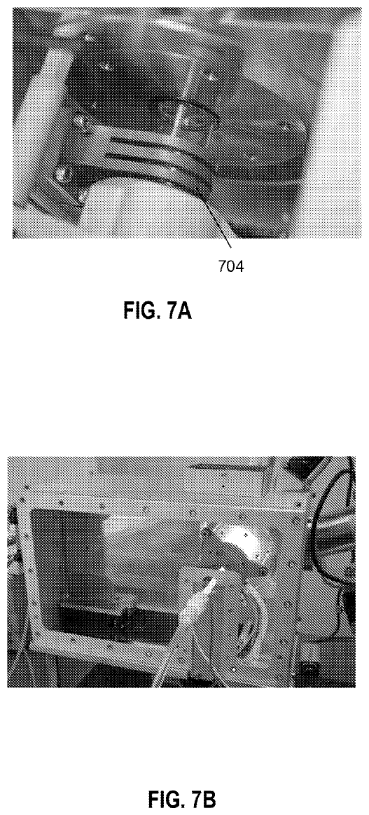

FIG. 7A shows a photograph of a load coil 704 around a tube. Load coil 704 is machined rather than formed from a tube. Machining increases mechanical accuracy of the coils and therefore improves reproducibility of the analytical results when different but similar in design coils are used (e.g., from replacing a coil or from analysis on a different instrument).

FIG. 7B shows a photo of operation of the ICP torch. FIG. 7B shows operation of a solid-state RF generator with a sealed torch.

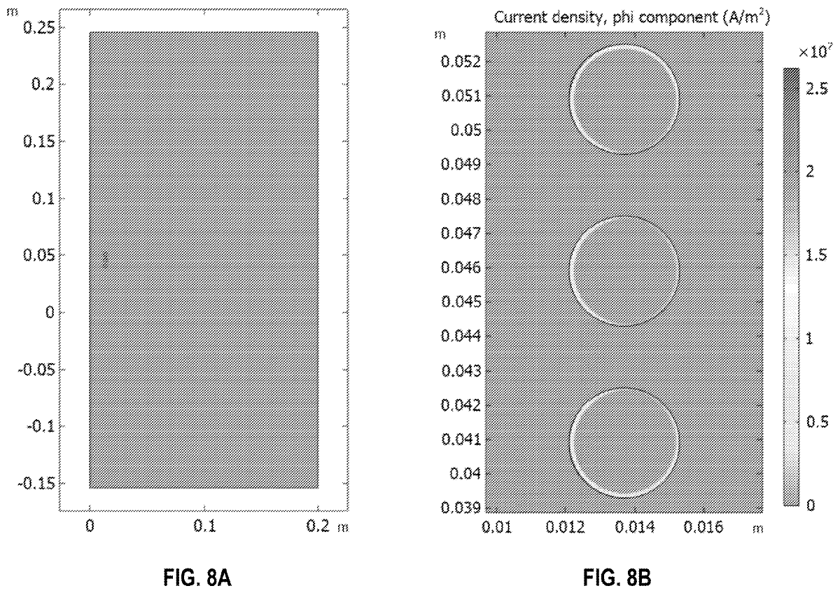

FIGS. 8A and 8B show results of simulations of distribution of the current density inside turns of the load coil with round circular turns. The load coil may be a load coil with turns connected in parallel as described herein. FIG. 8A shows the simplified geometry of simulations that includes three cylindrically symmetrical coil turns simulated in sufficiently large empty space. The x-axis is the radius. The y-axis is the axial direction. FIG. 8B is a zoomed-in graph of the cross-section of the coil turns and the calculated current density at RF frequency f=100 kHz. Two different effects are seen. First, the electrical current is situated near surface of the coil. This is a well-known skin effect, with the thickness of the current layer is proportional to f^{-1/2}. Second, the current is shifted to the inner part of the coil (to the left on the figure). If f is increased to a typical operating frequency of 27 MHz, the distribution remains qualitatively the same, but the thickness of the current layer becomes so small (few micrometers) that the current layer becomes too thin to be shown in the picture at this dimensional scale. Thus, the illustration is done at the lower frequency where the skin effect is easy to notice. The current flows on the inner surface of the coil and the small current layer may allow for modifying the coil geometry. For example, the coil can be potentially manufactured as a deposition of a thin copper layer on a surface of ceramics, as described earlier. The thin layer of conductor in the areas of high current density may be sufficient to create nearly identical RF fields using RF currents in these layers.

### D. Example Systems

Embodiments include an RF coil resonator. The RF coil resonator may include a plurality of loops. Each loop of the plurality of loops may be geometrically parallel to the other loops of the plurality of loops. Each loop of the plurality of loops may include a flat surface parallel to the closest surface of the adjacent loop. Each loop may be load coil 104 in FIG. 1 or load coil 204 in FIG. 2. The plurality of loops may be load coil 504 in FIG. 5, load coil 612 in FIG. 6, or load coil 704 in FIG. 7.

Each loop of the plurality of loops may form a discontinuous circle. The plurality of loops may be configured such that a center of curvature of each loop of the plurality of loops lies on a longitudinal axis. The longitudinal axis is orthogonal to each plane comprising each loop of the plurality of loops. The plurality of loops may include at least 2, 3, 4, 5, 6, 7, 8, 9, or more loops. The plurality of loops may be an odd number or an even number. In embodiments, there are no other loops in electrical communication with the plurality of loops.

Each loop of the plurality of loops may define an aperture. The aperture may be circular in shape. In embodiments, the aperture may not be completely circular but over 60%, 70%, 80%, 90%, 95%, or 99% circular (the percentage being the overall percentage of the circumference of the circle defined by the loop). The aperture may include a portion extending from the circular portion of the aperture. The portion may be rectangular in shape. The aperture may be in the shape of a lollipop, with a stick protruding from a circle. A cross section of each loop may be a square, rectangle, or circle. The cross section may be of the portion of the loop with the smallest cross-sectional area.

Each loop of the plurality of loops may be connected to the other loops of the plurality of loops to be electrically parallel when a voltage is applied to the plurality of loops. Each loop may have a first terminal, with the first terminal on the same end of each loop. The first terminals of the loops may directly contact a first conductive piece. Each loop may have a second terminal, with the second terminal on the same end of each loop, but the second terminal being on a different end as the first terminal. The second terminals of the loops may directly contact a second conductive piece. The first conductive piece and the second conductive piece may not contact each other. The first conductive piece and the second conductive piece may be a copper bar. In embodiments, the current reaches all loops at the same time or about the same time unlike a plurality of loops electrically connected in series.

The plurality of loops may be machined from a single piece of metal (e.g., copper or silver). For example, a piece of metal may have parallel slits formed, which separate one loop from another. The piece of metal may have a hole drilled to form the circular aperture in the plurality of loops.

Each loop of the plurality of loops may be characterized by the same radius of curvature. For example, the plurality of apertures may each have congruent shapes, including congruent circular shapes.

The discontinuous circle may be the result of a single insulating section, two insulating sections, three insulating sections, or more. For example, a loop with two insulating sections may include both first half-turn coil 304 and second half-turn coil 308 of FIG. 3. A capacitor may electrically couple the first terminal to the second terminal. A capacitor may bridge one of each of the insulating sections. The capacitor may be resonant capacitor 348 or resonant capacitor 348.

A loop between two other loops may have a smaller radius of curvature than the two other loops. The loop at the end (i.e., having only one adjacent loop) may be larger than a loop in the middle (i.e., having two adjacent loops).

Each loop of the plurality of loops may include an insulating material (e.g., ceramic) coated with a conductive thin film. In some embodiments, a non-complete subset of the plurality of loops may include the insulating material coated with a conductive thin film.

The RF coil resonator may also include a power supply in electrical communication with the plurality of loops. Two components may be considered to be in electrical communication with each other if connected with a switch or transistor, even when the switch or transistor is in the off position. The power supply may be in a circuit configured to deliver a first phase of RF power to a first terminal of the plurality of loops and a second phase of RF power to a second terminal of the plurality of loops. The power supply may include DC power supply 420. The power supply may be a switch-mode power supply. The circuit may be an RF delivery circuit that delivers power to a resonant RF tank circuit.

The RF coil resonator may include a resonant RF tank circuit in electrical communication with the plurality of loops. The resonant RF tank circuit may include a capacitor and an inductor. The circuit (e.g., RF power delivery circuit) configured to deliver the first phase of the RF power to the plurality of loops may deliver the first phase of the RF power to the plurality of loops through the RF tank circuit including the capacitor and the inductor. The resonant RF tank circuit may include 2, 3, 4, 5, 6, 7, 8, 9, 10, or more capacitors. The resonant RF tank circuit may include 2, 3, 4, 5, 6, 7, 8, 9, 10, or more inductors. The resonant RF tank circuit may include RF tank circuit 402.

The RF power delivery circuit may include transistors to gate the delivery of RF power to the plurality of loops. The transistors may include gallium nitride or silicon carbide transistors. The RF power delivery circuit may include 1, 2, 3, 4, 5, 6, 7, 8, 9, 10, or more transistors. Power handling characteristics of transistors may be from 100 W to 5 kW. Several transistors may be operated in parallel to increase power handling capacity. Full bridge operation utilizes four transistors, which effectively shares the parasitic power dissipation between four transistors. Operating frequency may be selected to be above the target frequency of operation for the ICP torch. For example, the torch can operate at 30 MHz while the transistors may have their operating frequency limit at 100 MHz. ICP operating frequencies may be in the range of a few MHz to few hundred MHz. The RF power delivery circuit may deliver the second phase of RF power to the second terminal. The RF power delivery circuit may be parts of the circuit that are not the resonant RF tank circuit.

The RF coil resonator may include a tube. The plurality of loops may be disposed around the tube. The tube may be quartz. The tube may be cylindrical. The tube may be centered within the plurality of loops.

Embodiments may include a module including any RF coil resonator described herein and a sampler. The sampler may include sampler 608. The sampler may be configured to provide a path from plasma effluents from a plasma ignited and/or maintained by the load coil to flow into a chamber in the sampler. The plasma torch plus RF supply module without the sampler may be less than 30 cm long and 20 cm wide and 4 cm deep. An analysis system with the module may also include a detector. The detector may be a detector in a mass spectrometer, an optical detector in an optical emission spectroscopy system, or other detector.

The RF coil resonator may be used in any methods of analysis using a plasma described herein.

Embodiments may include an RF power module. The RF power module may include the RF power delivery circuit. The RF power module may include a DC power supply. The DC power supply may be any power supply described herein, including DC power supply 420. The RF power module may also include a plurality of transistors in electrical communication with the DC power supply. The plurality of transistors may be any transistor described herein.

The RF power module may include a plurality of gate drivers. Each gate driver of the plurality of gate drivers may be connected to a separate transistor of the plurality of transistors. For example, the number of transistors may equal the number of gate drivers. The gate drivers may be any gate drivers described herein, including those in FIG. 4.

The RF power module may include a processor. The processor may be configured to control the plurality of gate drivers to open and close the plurality of transistors in order to convert DC current from the DC power supply into RF current. The instructions for the gate drivers may be stored on a non-tangible computer readable medium.

The RF power module may include a plasma load coil. The plasma load coil may be in electrical communication with the DC power supply. The plasma load coil, the plurality of transistors, and the DC power supply may be arranged such that the RF current produced from the processor controlling the plurality of gate drivers is delivered to the plasma load coil. The plasma load coil may be any load coil described herein.

The RF power module may include a capacitor and an inductor. The capacitor, the inductor, the plurality of transistors, and the DC power supply may be arranged such that the RF current produced from the processor controlling the plurality of gate drivers is delivered to the inductor. The capacitor or inductor may be any described herein. The RF power module may include a plurality of capacitors and/or a plurality of inductors.

### II. Example Methods

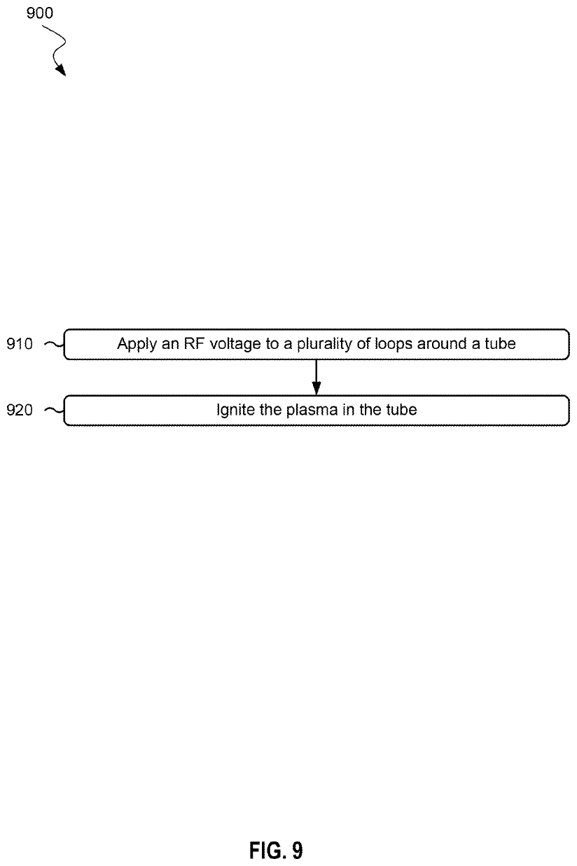

FIG. 9 is a flowchart of an example process 900 associated with a method of analysis using a plasma. In some implementations, one or more process blocks of FIG. 9 may be performed by an RF coil resonator (e.g., load coil configuration 100, load coil configuration 200, load coil configuration 300, and/or plasma torch module 600). In some implementations, one or more process blocks of FIG. 9 may be performed by another device or a group of devices separate from or including the RF coil resonator. Additionally, or alternatively, one or more process blocks of FIG. 9 may be performed by one or more components of plasma torch module 600, such as ICP tube 604, sampler 608, or load coil 612.

At block 910, process 900 may include applying an RF voltage to a plurality of loops around a tube. The plurality of loops may be electrically parallel. A first phase of the RF voltage may be applied to a first terminal of the plurality of loops. A second phase of the RF voltage may be applied to a second terminal of the plurality of loops. The first phase may be opposite the second phase. For example, the first phase may be the negative of the second phase. The plurality of loops may be any plurality of loops described herein, including load coil 504 in FIG. 5, load coil 612 in FIG. 6, or load coil 704 in FIG. 7. Each loop may be load coil 104 in FIG. 1 or load coil 204 in FIG. 2.

Applying the RF voltage comprises applying a power in a range from 0.10 to 20 kW. The RF voltage may be 100 V to 6 kV. Voltage may be applied at a frequency from 900 kHz to 100 MHz, including 27.12 MHz and 40 MHz. Applying the RF voltage may be with using the power supply, circuits, or other electronic components described herein. Gas pressure for the ignition of the plasma may be applied before applying the RF voltage.

At block 920, process 900 may include igniting the plasma in the tube. In embodiments, igniting the plasma does not include applying voltage to an electrode inside the tube. Igniting the plasma may be at a pressure in a range from 0.5 to 20 Torr. The pressure of the plasma may be increased (e.g., to 0.5 to 20 atm), which may be pressures associated with typical analytical conditions. Analytical data resulting from the plasma may be acquired, including any analytical data described herein.

Process 900 includes flowing a first gas through the plasma to form a second gas comprising plasma effluents. Process 900 may include flowing a sample and the first gas through the plasma to form the second gas. Process 900 may also include flowing the second gas to a detector to be analyzed. The detector may be any detector descried herein.

Process 900 may include additional implementations, such as any single implementation or any combination of implementations described below and/or in connection with one or more other processes described elsewhere herein.

Although FIG. 9 shows example blocks of process 900, in some implementations, process 900 may include additional blocks, fewer blocks, different blocks, or differently arranged blocks than those depicted in FIG. 9. Additionally, or alternatively, two or more of the blocks of process 900 may be performed in parallel.

### III. Embodiments

Embodiments may include the following.

Embodiment 1: A method of analysis using a plasma, the method comprising: applying an RF voltage to a plurality of loops around a tube, wherein: the plurality of loops is electrically parallel, a first phase of the RF voltage is applied to a first terminal of the plurality of loops, a second phase of the RF voltage is applied to a second terminal of the plurality of loops, and the first phase is opposite the second phase; and igniting the plasma in the tube.

Embodiment 2: The method of embodiment 1, wherein applying the RF voltage comprises applying a power in a range from 100 W to 5 kW.

Embodiment 3: The method of embodiment 1, wherein the RF voltage is 100 V to 6 kV.

Embodiment 4: The method of embodiment 1, wherein igniting the plasma does not comprise applying voltage to an electrode inside the tube.

Embodiment 5: The method of embodiment 1, wherein igniting the plasma is at a pressure in a range from 0.5 to 20 Torr.

Embodiment 6: The method of embodiment 1, further comprising: flowing a first gas through the plasma to form a second gas comprising plasma effluents.

Embodiment 7: The method of embodiment 6, further comprising: flowing a sample and the first gas through the plasma to form the second gas, and flowing the second gas to a detector to be analyzed. Embodiments 1-7 may be combined with any method described herein.

Embodiment 8: An RF coil resonator, the RF coil resonator comprising: a plurality of loops, wherein: each loop of the plurality of loops is connected to the other loops of the plurality of loops to be electrically parallel when a voltage is applied to the plurality of loops, each loop of the plurality of loops is geometrically parallel to the other loops of the plurality of loops, each loop of the plurality of loops forms a discontinuous circle, the plurality of loops is configured such that a center of curvature of each loop of the plurality of loops lies on a longitudinal axis, and the longitudinal axis is orthogonal to each plane comprising each loop of the plurality of loops; and a power supply in electrical communication with the plurality of loops, the power supply in a circuit configured to deliver a first phase of RF power to a first terminal of the plurality of loops and a second phase of RF power to a second terminal of the plurality of loops. Embodiment 8 may be any RF coil resonator described herein.

The specific details of particular embodiments may be combined in any suitable manner without departing from the spirit and scope of embodiments of the invention. However, other embodiments of the invention may be directed to specific embodiments relating to each individual aspect, or specific combinations of these individual aspects.

The above description of example embodiments of the invention has been presented for the purposes of illustration and description. It is not intended to be exhaustive or to limit the invention to the precise form described, and many modifications and variations are possible in light of the teaching above.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Additionally, details of any specific embodiment may not always be present in variations of that embodiment or may be added to other embodiments.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither, or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a method” includes a plurality of such methods and reference to “the capacitor” includes reference to one or more capacitors and equivalents thereof known to those skilled in the art, and so forth. The invention has now been described in detail for the purposes of clarity and understanding. However, it will be appreciated that certain changes and modifications may be practice within the scope of the appended claims.

All publications, patents, and patent applications cited herein are hereby incorporated by reference in their entirety for all purposes. None is admitted to be prior art.

1. An RF coil resonator, the RF coil resonator comprising:
a plurality of loops, wherein:
each loop of the plurality of loops is connected to the other loops of the plurality of loops to be electrically parallel when a voltage is applied to the plurality of loops; and
a power supply in electrical communication with the plurality of loops, the power supply in a circuit configured to deliver a first phase of RF power to a first terminal of the plurality of loops and a second phase of RF power to a second terminal of the plurality of loops.

2. The RF coil resonator of claim 1, wherein each loop of the plurality of loops is geometrically parallel to the other loops of the plurality of loops.

3. The RF coil resonator of claim 1, wherein:
the plurality of loops is configured such that a center of curvature of each loop of the plurality of loops lies on a longitudinal axis, and
the longitudinal axis is orthogonal to each plane comprising each loop of the plurality of loops

4. The RF coil resonator of claim 1, wherein each loop of the plurality of loops comprises a flat surface parallel to a closest surface of an adjacent loop.

5. The RF coil resonator of claim 1, wherein each loop of the plurality of loops is characterized by the same radius of curvature.

6. The RF coil resonator of claim 1, wherein each loop of the plurality of loops forms a discontinuous circle.

7. The RF coil resonator of claim 6, wherein the discontinuous circle is the result of a single insulating section.

8. The RF coil resonator of claim 7, further comprising a capacitor electrically coupling the first terminal to the second terminal.

9. The RF coil resonator of claim 6, wherein the discontinuous circle is the result of two insulating sections.

10. The RF coil resonator of claim 9, further comprising two capacitors, wherein each capacitor of the two capacitors bridges one of the two insulating sections.

11. The RF coil resonator of claim 1, further comprising:
a tube, wherein the plurality of loops is disposed around the tube.

12. The RF coil resonator of claim 1, wherein the first terminal is opposite the second terminal.

13. The RF coil resonator of claim 1, wherein the plurality of loops comprises at least three loops.

14. The RF coil resonator of claim 13, wherein a loop between two other loops has a smaller radius of curvature than the two other loops.

15. The RF coil resonator of claim 1, wherein the power supply is a switch-mode power supply.

16. The RF coil resonator of claim 1, further comprising:
a capacitor, and
an inductor, wherein:
the circuit is configured to deliver the first phase of the RF power to the plurality of loops through the capacitor and the inductor.

17. The RF coil resonator of claim 1, wherein the circuit comprises a transistor to gate the delivery of RF power to the plurality of loops.

18. The RF coil resonator of claim 1, wherein each loop of the plurality of loops comprises a ceramic coated with a conductive thin film.

19. A module comprising the RF coil resonator of claim 1 and a sampler.

20. A system comprising the module of claim 19 and a detector.

21. An RF power module, the RF power module comprising:
a DC power supply;
a plurality of transistors in electrical communication with the DC power supply;
a plurality of gate drivers, each gate driver of the plurality of gate drivers is connected to a separate transistor of the plurality of transistors; and
a processor; wherein:
the processor is configured to control the plurality of gate drivers to open and close the plurality of transistors in order to convert DC current from the DC power supply into RF current.

22. The RF power module of claim 21, wherein the conversion of DC current into RF current utilizes resonant conversion technology.

23. The RF power module of claim 21, further comprising:
a plasma load coil, wherein:
the plasma load coil is in electrical communication with the DC power supply, and
the plasma load coil, the plurality of transistors, and the DC power supply are arranged such that the RF current produced from the processor controlling the plurality of gate drivers is delivered to the plasma load coil.

24. The RF power module of claim 21, further comprising:
a capacitor, and
an inductor, wherein:
the capacitor, the inductor, the plurality of transistors, and the DC power supply are arranged such that the RF current produced from the processor controlling the plurality of gate drivers is delivered to the inductor.

25. The RF power module of claim 21, wherein the plurality of transistors are gallium nitride transistors.
